(19) United States
(12) Patent Application Publication
(10) Pub. No.: US 2025/0234659 A1
(43) Pub. Date: Jul. 17, 2025

(54) SEMICONDUCTOR STRUCTURE INCLUDING PHOTODETECTOR AND MANUFACTURING METHOD THEREOF

(71) Applicant: Taiwan Semiconductor Manufacturing Company, Ltd., Hsinchu (TW)

(72) Inventors: Chen-Hao Chiang, Taoyuan City (TW); Chen-Hua Yu, Hsinchu City (TW); Li-Weng Chang, New Taiepi City (TW); Jiun-Yi Wu, Taoyuan City (TW)

(73) Assignee: Taiwan Semiconductor Manufacturing Company, Ltd., Hsinchu (TW)

(21) Appl. No.: 18/409,806

(22) Filed: Jan. 11, 2024

(51) Int. Cl. H01L 31/107; H01L 31/0352; H01L 31/18

(52) U.S. Cl. CPC H10F 30/2255; H10F 71/121; H10F 77/147

(57) ABSTRACT

A semiconductor structure includes a substrate including a first semiconductor material, a first doped region disposed in the substrate and having a first conductivity type, a second doped region disposed in the substrate and separated from the first doped region, a first epitaxial region disposed in a cavity of the substrate, and a second epitaxial region disposed in the cavity of the substrate and connected to the first epitaxial region. The second doped region has a second conductivity type different than the first conductivity type. The first epitaxial region includes the first semiconductor material with an impurity of the second conductivity type, and the second epitaxial region includes a second semiconductor material different than the first semiconductor material.

### BACKGROUND

Many modern-day electronic devices (e.g., smartphones, digital cameras, imaging devices, etc.) include image sensors. The image sensors include one or more photodetectors (e.g., photodiodes, photo-transistors, photo-resistors, etc.) configured to absorb incident radiation and output electrical signals corresponding to the incident radiation. Some image sensors are based on an avalanche photodiode (APD) which is introduced as a highly-sensitive light receiving device. The APD has a high response speed, the function of an amplifier, high quantum efficiency and a low operational voltage. Although existing semiconductor structures with photodetectors are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-7A and 8-10 illustrate schematic cross-sectional views of intermediate stages in the manufacturing of a semiconductor structure with a photodetector, in accordance with some embodiments.

FIG. 7B illustrates a schematic top-down view of the cavity in FIG. 7A, in accordance with some embodiments.

FIGS. 11-12 illustrate schematic cross-sectional views of intermediate stages in the manufacturing of a semiconductor structure with a photodetector, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

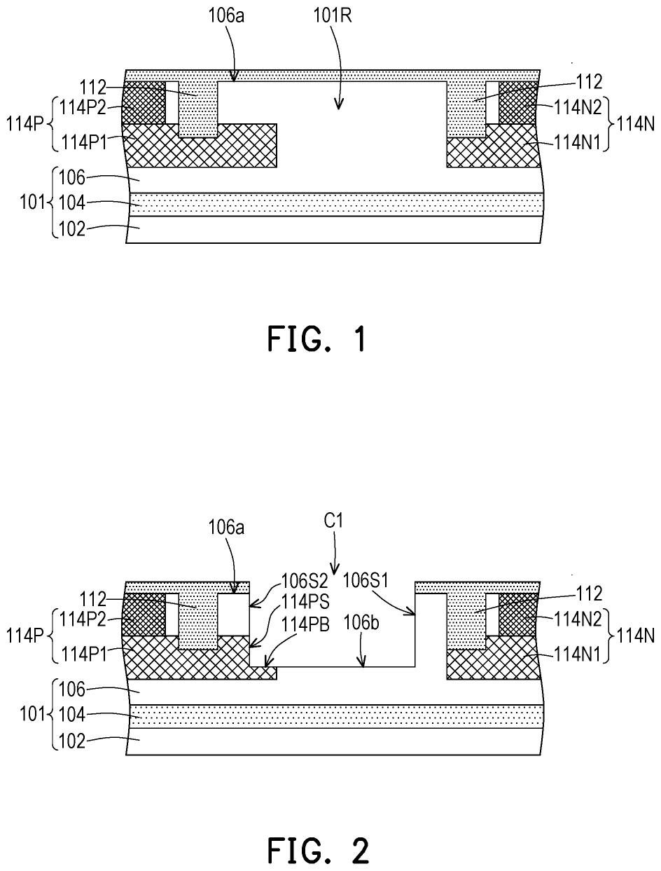

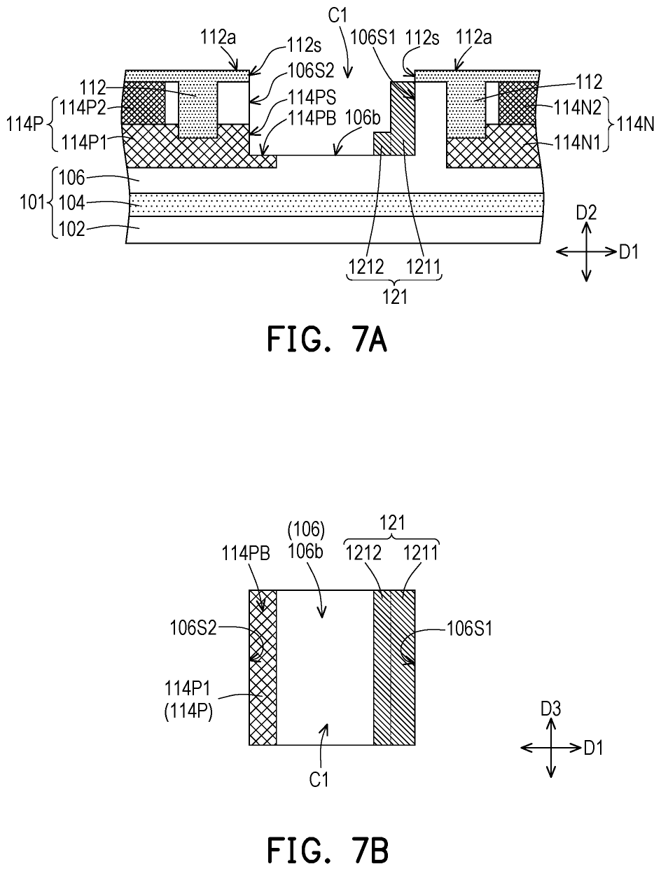

FIGS. 1-7A and 8-10 illustrate schematic cross-sectional views of intermediate stages in the manufacturing of a semiconductor structure with a photodetector, and FIG. 7B illustrates a schematic top-down view of the cavity in FIG. 7A, in accordance with some embodiments.

Referring to FIG. 1, a substrate 101 may be provided. In some embodiments, the substrate 101 is a semiconductor-on-insulator (SOI) substrate. For example, the substrate 101 includes a first semiconductor layer 102 and a second semiconductor layer 106 vertically separated from each other by an insulating layer 104. The first semiconductor layer 102 and/or the second semiconductor layer 106 may be or include a semiconductor material (e.g., silicon, germanium, or the like) or other suitable semiconductor material(s). In some embodiments, the semiconductor material of the second semiconductor layer 106 is the same semiconductor material as the semiconductor material of the first semiconductor layer 102. The insulating layer 104 may be disposed on the first semiconductor layer 102. The insulating layer 104 may be or include an oxide (e.g., silicon dioxide), aluminum oxide, titanium oxide, tantalum oxide, or the like), a high-k dielectric, suitable electrical insulator, or a combination thereof. The second semiconductor layer 106 may be disposed on the insulating layer 104. For example, the first semiconductor layer 102 is a silicon layer, the insulating layer 104 is a silicon dioxide layer, and the second semiconductor layer 106 is a silicon layer. In some embodiments, the substrate 101 is formed by sequentially depositing the insulating layer 104 and the second semiconductor layer 106 on the first semiconductor layer 102 by using a deposition process such as physical vapor deposition (PVD), chemical vapor deposition (CVD), atomic layer deposition (ALD), or the like. It should be noted that the substrate 101 may have a different material and type than shown.

In some embodiments, an isolation structure 112 is formed in and on the substrate 101. For example, the isolation structure 112 is formed on an upper surface 106a of the second semiconductor layer 106 and extends into the second semiconductor layer 106. In some embodiments, the isolation structure 112 surrounds a predetermined active region 101R in the substrate 101. The isolation structure 112 may be disposed over the insulating layer 104 and vertically spaced from the insulating layer 104. The isolation structure 112 may be or include an oxide (e.g., silicon dioxide), a nitride (e.g., silicon nitride), suitable electrically isolating material, or a combination thereof. The isolation structure 112 may include one or more liner (e.g., silicon nitride liner or the like). A process for forming the isolation structure 112 may include forming a trench in the second semiconductor layer 106 of the substrate 101; depositing an electrically isolating material into the trench using a deposition process such as CVD, PVD, ALD, or the like. In some embodiments, the isolation structure 112 is also formed on the upper surface 106a of the second semiconductor layer 106. In some embodiments, a lower portion of the isolation structure 112 laterally surrounded by the substrate 101 is viewed as shallow trench isolation (STI) portion, and an upper portion of the isolation structure 112 disposed on the upper surface 106a of the second semiconductor layer 106 is viewed as a passivation portion. The portion of the isolation structure 112 overlying the upper surface 106a of the second semiconductor layer 106 may not (or may) be subsequently removed afterwards by way of a planarization process.

With continued reference to FIG. 1, a first doped region 114N and a second doped region 114P may be formed into the substrate 101. For example, the first doped region 114N and a second doped region 114P are formed in the second semiconductor layer 106 and over the insulating layer 104. The first doped region 114N and a second doped region 114P may be vertically spaced apart from the insulating layer 104. The first doped region 114N may be a region of the second semiconductor layer 106 having a conductivity type (e.g., n-type). For example, the first doped region 114N includes dopants such as phosphorus, arsenic, or the like. The second doped region 114P may be a region of the second semiconductor layer 106 having a different conductivity type (e.g., p-type) than the conductivity type of the first doped region 114N. For example, the second doped region 114P includes dopants such as boron, gallium, or the like.

The first doped region 114N may include a first lower region 114N1 and a first upper region 114N2 disposed on and electrically coupled to the first lower region 114N1. In some embodiments, the first upper region 114N2 extends vertically from the upper surface 106a of the second semiconductor layer 106 to the first lower region 114N1. The second doped region 114P may include a second lower region 114P1 and a second upper region 114P2 disposed on and electrically coupled to the second lower region 114P1. In some embodiments, the second upper region 114P2 extends vertically from the upper surface 106a of the second semiconductor layer 106 to the second lower region 114P1. The first upper region 114N2 and the second upper region 114P2 may be formed in the second semiconductor layer 106 of the substrate 101 respectively on opposing sides of the isolation structure 114. The first lower region 114N1 and the second lower region 114P1 may be formed below the isolation structure 112. In some embodiments, the first lower region 114N1 and the second lower region 114P1 surround the lower portion of the isolation structure 112. In some embodiments, the first lower region 114N1 is formed to be laterally separated from the second lower region 114P1 by an undoped portion of the substrate 101.

With continued reference to FIG. 1, the first upper region 114N2 may have a doping concentration greater than a doping concentration of the first lower region 114N1. In some embodiments, the first upper region 114N2 serves as a contact region (e.g., n+ contact region). A process for forming the first doped region 114N may include performing a doping process on the substrate 101 that includes, for example, implanting the dopants (e.g., n-type dopants) into the substrate 101. The first upper region 114N2 may be formed such that a concentration of the dopants in the first upper region 114N2 is greater than in the first lower region 114N1. The second upper region 114P2 may have a doping concentration greater than a doping concentration of the second lower region 114P1. In some embodiments, the second upper region 114P2 serves as a contact region (e.g., p+ contact region). A process for forming the second doped region 114P may include performing a doping process on the substrate 101 that includes, for example, implanting the dopants (e.g., p-type dopants) into the substrate 101. The second upper region 114P2 may be formed to have a doping concentration greater than a doping concentration in the second lower region 114P1.

Still referring to FIG. 1, the isolation structure 112 may be at least partially disposed in the first doped region 114N and/or at least partially disposed in the second doped region 114P. For example, the STI portion of the isolation structure 112 extends vertically into the second semiconductor layer 106 to a position disposed in the first doped region 114N and/or the second doped region 114P. In some embodiments, the isolation structure 112 is formed before the doping process. In alternative embodiments, the lower regions of the first doped region 114N and the second doped region 114P are formed before the formation of the isolation structure 112, and the upper regions of the first doped region 114N and the second doped region 114P are formed after the formation of the isolation structure 112. It is appreciated that these steps are not limiting in that the order of the steps may be altered in other embodiments to form the isolation structure 112, the first doped region 114N, and the second doped region 114P.

Referring to FIG. 2 and with reference to FIG. 1, a cavity C1 may be formed through a portion of the isolation structure 112 on the upper surface 106a of the substrate 101 and extend into the substrate 101. For example, the cavity C1 extends from the upper surface 106a of the second semiconductor layer 106 into the active region 101R of the substrate 101. The cavity C1 may be separated from and surrounded by the isolation structure 112 in the substrate 101. The cavity C1 may be formed by: depositing a hard mask layer (not shown) over the substrate 101; patterning the hard mask layer by lithography/etching processes; and performing one or more etching process (e.g., a dry etch process, a wet etch process, a combination thereof, or the like) into the substrate 101 with the patterned hard mask layer in place. In alternative embodiments, the cavity C1 is formed by any other suitable patterning process.

As illustrated by the cross-sectional view of FIG. 2, a first inner sidewall 106S1 of the second semiconductor layer 106, a second inner sidewall 106S2 of the second semiconductor layer 106 opposite to the first inner sidewall 106S1, and a lower surface 106b of the second semiconductor layer 106 connected to the first and second inner sidewalls (106S1 and 106S2) may be accessibly exposed by the cavity C1. For example, the first inner sidewall 106S1 is close to the first doped region 114N and away from the second doped region 114P, while the second inner sidewall 106S2 is close to the second doped region 114P and away from the first doped region 114N. In some embodiments, a portion of the second lower region 114P1 is removed during/after the formation of the cavity C1. For example, the second lower region 114P1 includes a sidewall 114PS and a lower surface 114PB that are accessibly exposed by the cavity C1, where the lower surface 114PB is connected to the sidewall 114PS. In some embodiments, the lower surface 114PB of the second lower region 114P1 is substantially leveled with the lower surface 106b of the second semiconductor layer 106, within process variations. In some embodiments, the sidewall 114PS of the second lower region 114P1 is substantially leveled with the first inner sidewall 106S1 of the second semiconductor layer 106, within process variations.

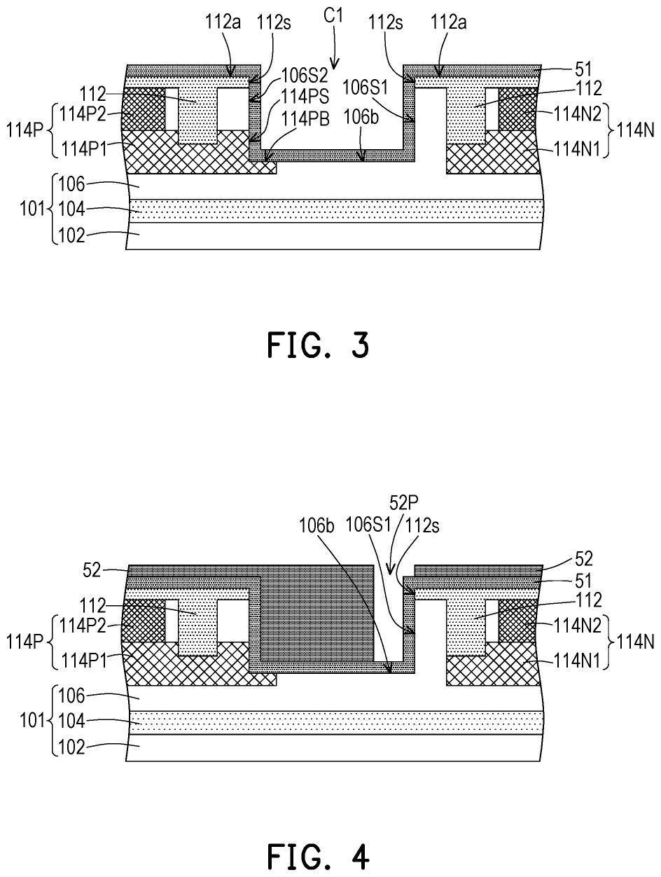

Referring to FIG. 3 and with reference to FIG. 2, a first masking layer 51 may be formed in the cavity C1 and over the substrate 101. The first masking layer 51 may be or include an oxide, a nitride, a combination thereof, the like, and/or some other suitable masking material. The first masking layer 51 may be formed by any suitable deposition process such as CVD, PVD, ALD, sputtering, or the like. The first masking layer 51 may be conformally formed on the passivation portion of the isolation structure 112 and in the cavity C1 to cover the upper surface 112a and the inner sidewall 112s of the isolation structure 112, the first and second inner sidewalls (106S1 and 106S2), and the lower surface 106b of the second semiconductor layer 106. In some embodiments where the portion of the first lower region 114P1 is accessibly exposed by the cavity C1, the lower surface 114PB and the sidewall 114PS of the second lower region 114P1 that are accessibly exposed by the cavity C1 may be covered by the first masking layer 51. In some embodiment where a portion of the first doped region 114N is accessibly exposed by the cavity C1, the first masking layer 51 may cover the exposed surface(s) of the portion of the first doped region 114N.

Referring to FIG. 4 and with reference to FIG. 3, a second patterned masking layer 52 may be formed on the first masking layer 51. For example, the second patterned masking layer 52 includes an opening 52P accessibly exposing a portion of the first masking layer 51, and this exposed portion of the first masking layer 51 overlies the first inner sidewall 106S1, a portion of the inner sidewall 112s of the isolation structure 112 connected to the first inner sidewall 106S1, and a portion of the lower surface 106b of the second semiconductor layer 106 connected to the first inner sidewall 106S1. The material of the second patterned masking layer 52 may be different from the material of the first masking layer 51. For example, the second patterned masking layer 52 is a photoresist with an opening. In some embodiments, the second patterned masking layer 52 is formed by: depositing a photoresist material on the first masking layer 51 through any suitable deposition process such as spin-coating, CVD, or the like; and patterning the photoresist material to form the opening 52P through exposing and developing processes or the like. The remaining photoresist material forms the second patterned masking layer 52 which may protect the underlying material from subsequent processing steps.

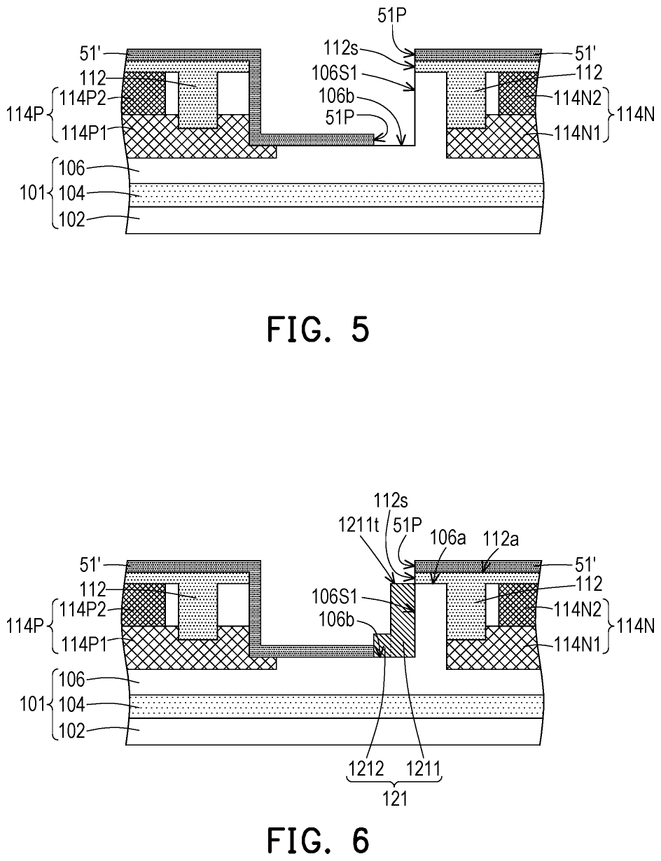

Referring to FIG. 5 and with reference to FIG. 4, the portion of the first masking layer 51 accessibly exposed by the opening 52P of the second patterned masking layer 52 may be removed. For example, one or more etching process (e.g., a dry etch process, a wet etch process, a combination thereof, or the like) is performed to form a first patterned masking layer 51′ with an opening 51P. The etching process may be performed using the second patterned masking layer 52 as an etching mask. For example, the etching process selectively removes the portion of the first masking layer 51 accessibly exposed by the opening 52P. The second patterned masking layer 52 may then be removed through any suitable process such as ashing, stripping, etching, a combination thereof, etc., and optionally followed by a cleaning process before forming the subsequent growing process. As illustrated by the cross-sectional view of FIG. 5, the first inner sidewall 106S1, a portion of the inner sidewall 112s of the isolation structure 112 connected to the first inner sidewall 106S1, and a portion of the lower surface 106b of the second semiconductor layer 106 connected to the first inner sidewall 106S1 may be accessibly exposed by the opening 51P of the first patterned masking layer 51′.

Referring to FIG. 6 and with reference to FIG. 5, a first epitaxy region 121 may be formed on the second semiconductor layer 106 and in the opening 51P of the first patterned masking layer 51′. In some embodiments, a process for forming the first epitaxy region 121 includes epitaxially and selectively growing an epitaxially grown semiconductor material on the first inner sidewall 106S1 and a portion of the lower surface 106b of the second semiconductor layer 106, where the portion of the lower surface 106b is confined by the first patterned masking layer 51′ and exposes by the opening 51P. For example, the first epitaxy region 121 is formed through low-pressure chemical vapor deposition (LPCVD) or any suitable growing process. The epitaxially grown semiconductor material may include a conductivity type impurity. For example, a p-type semiconductor layer is epitaxially grown in the opening 51P and on the second semiconductor layer 106. The p-type semiconductor layer may be free from n-type impurities. For example, silicon boron (SiB) layer (or other suitable p-type semiconductor layer) is grown on the second semiconductor layer 106 as the first epitaxy region 121. In some embodiments, a p-type impurity is in-situ doped into the first epitaxy region 121 with the proceeding of the epitaxy. The first epitaxy region 121 may have a suitable impurity concentration to avoid the impurity to be undesirably diffused into the second semiconductor layer 106 and the subsequently-formed second epitaxy region. It is appreciated that the impurity concentration may vary depending upon the particular application.

In some embodiments, the first epitaxy region 121 includes a first portion 1211 and a second portion 1212 connected to the first portion 1211. For example, the first portion 1211 is in physical and direct contact with the first inner sidewall 106S1 and the lower surface 106b of the second semiconductor layer 106. The second portion 1212 may be in physical and direct contact with the lower surface 106b of the second semiconductor layer 106 and may be spaced apart from the first inner sidewall 106S1 by the first portion 1211. As illustrated by the cross-sectional view of FIG. 6, the height of the first portion 1211 measured in the thickness direction (e.g., D2 labeled in FIG. 7A) of the resulting structure may be greater than the height the second portion 1212. In some embodiments, an upper surface 1211t of the first portion 1211 is lower than the upper surface 112a of the isolation structure 112. In some embodiments, the upper surface 1211t of the first portion 1211 is substantially leveled with the upper surface 106a of the second semiconductor layer 106, within process variations. The upper surface 1211t of the first portion 1211 may be substantially flat or may be curved (e.g., concaved or convex). Depending on the recipe of the growing process, the first epitaxy region 121 may have a different cross-sectional shape than shown.

Referring to FIGS. 7A-7B and with reference to FIG. 6, the first patterned masking layer 51′ may be removed to accessibly expose the passivation portion of the isolation structure 112 and the second semiconductor layer 106 that were covered by the first patterned masking layer 51′. For example, one or more etching process is performed to remove the first patterned masking layer 51′. In some embodiments, a wet etching process is performed to remove the first patterned masking layer 51′. A cleaning process is optionally performed after the etching. As illustrated by the cross-sectional view of FIG. 7A, after the removal of the first patterned masking layer 51′, the upper surface 112a and the inner sidewall 112s of the isolation structure 112, the second inner sidewall 106S2 of the second semiconductor layer 106, and a portion of the lower surface 106b of the second semiconductor layer 106 that was covered by the first patterned masking layer 51′ are accessibly exposed. In some embodiments where the portion of the second lower region 114P1 is removed during/after the formation of the cavity C1, the lower surface 114PB and the sidewall 114PS of the second lower region 114P1 of the second doped region 114P may be accessibly exposed again after the removal of the first patterned masking layer 51′.

As illustrated by the cross-sectional view of FIG. 7A, the first epitaxy region 121 may have a widthwise direction in a first direction D1 and a heightwise direction in a second direction D2. The first direction D1 may be viewed as the thickness direction of the first portion 1211 of the first epitaxy region 1210. For example, the first direction D1 is substantially perpendicular to the second direction D2. As illustrated by the top-down view of FIG. 7B, the first epitaxy region 121 may have a lengthwise direction in the third direction D3 and the widthwise direction in the first direction D1. The third direction D3 may be substantially perpendicular to the second direction D2 and the first direction D1. It should be noted that the cavity C1 may have a different top-down view than shown.

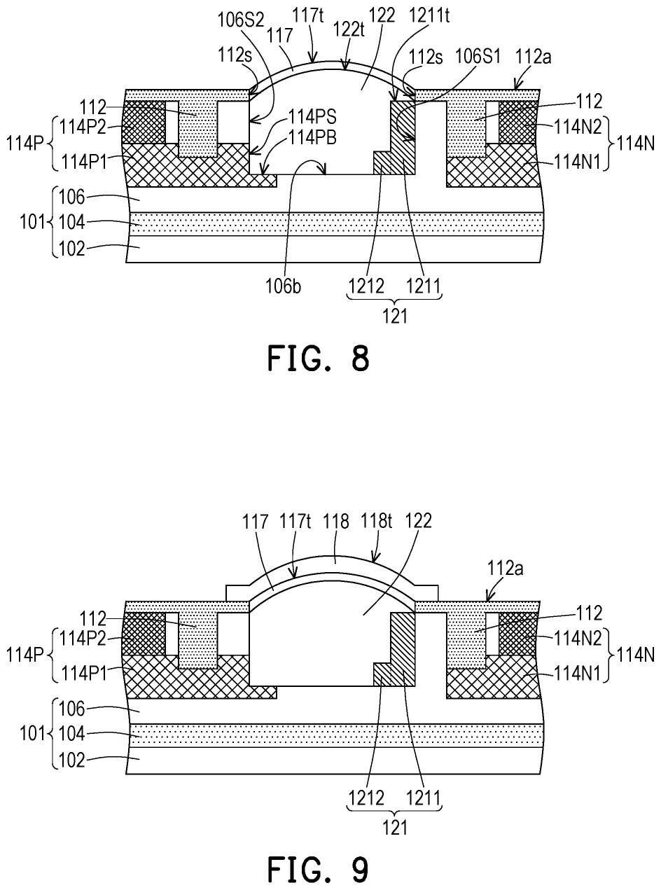

Referring to FIG. 8 and with reference to FIG. 7A, a second epitaxy region 122 may be formed in the cavity C1. For example, the second epitaxy region 122 is disposed on the second semiconductor layer 106 and the first epitaxy region 121. In some embodiments, a process for forming the second epitaxy region 122 includes epitaxially growing an epitaxially grown semiconductor material in the cavity C1. For example, the epitaxial process includes growing a semiconductor material (e.g., germanium) from the second semiconductor layer 106 and the first epitaxy region 121, thereby forming the second epitaxy region 122. The second epitaxy region 122 may be formed of a semiconductor material different than the semiconductor material of the first epitaxy region 121. In some embodiments, the semiconductor material of the second epitaxy region 122 is different than the semiconductor material of the second semiconductor layer 106. For example, the second epitaxy region 122 has the semiconductor material with a different band gap than the second semiconductor layer 106 and the semiconductor material of the first epitaxy region 121. In some embodiments, the semiconductor material of the second epitaxy region 122 has a wider band gap than the semiconductor material(s) of the substrate 101 to better absorb higher wavelengths of light. In some embodiments, the second semiconductor layer 106 includes a first semiconductor material (e.g., silicon), and the second epitaxy region 122 includes a second semiconductor material different than the first semiconductor material (e.g., germanium). In some embodiments, the second epitaxy region 122 is a germanium-containing layer. In some embodiments, the second epitaxy region 122 includes a single semiconductor material (e.g., germanium). Compared to silicon, germanium has a wider band gap and is better at absorbing higher wavelengths of light. It will be appreciated that other types of combinations of different epitaxially grown semiconductor materials may be used to form the second epitaxy region 122.

In some embodiments, the second epitaxy region 122 is physically connected to the second inner sidewall 106S2 and the lower surface 106b of the second semiconductor layer 106. In some embodiments, the second epitaxy region 122 is physically connected to the sidewall 114PS and the lower surface 114PB of the second lower region 114P1. In some embodiments, the second epitaxy region 122 is physically connected to outer surfaces of the first portion 1211 and the second portion 1212 of the first epitaxy region 121 which face away the first inner sidewall 106S1. In some embodiments, an upper surface 122t of the second epitaxy region 122 is curved or rounded. For example, the upper surface 122t of the second epitaxy region 122 is convex and arcs continuously between the first and second inner sidewalls 106S1 and 106S2. In some embodiments, the topmost point of the upper surface 122t of the second epitaxy region 122 is above the topmost point of the upper surface 112a of the isolation structure 112. In alternative embodiments, the topmost point of the upper surface 122t of the second epitaxy region 122 is below the topmost point of the upper surface 112a of the isolation structure 112. In some embodiments, the upper surface 122t of the second epitaxy region 122 extends past the upper surface 1211t of the first portion 1211 of the first epitaxy region 121.

With continued reference to FIG. 8, a capping layer 117 may be formed on the second epitaxy region 122. In some embodiments, the capping layer 117 conformally covers the upper surface 122t of the second epitaxy region 122. For example, the capping layer 117 has an arced upper surface 117t that corresponds to the arced upper surface 122t of the second epitaxy region 122. The capping layer 117 may (or may not) extend to cover the upper surface 112a of the isolation structure 112. The capping layer 117 may be or include a nitride (e.g., silicon nitride), a semiconductor material (e.g., silicon, a silicon-germanium alloy, or the like), an oxide (e.g., silicon dioxide), or the like. In some embodiments in which the capping layer 117 is a semiconductor material, the capping layer 117 may have different chemical composition than the second epitaxy region 122 and does not extend to cover the upper surface 112a of the isolation structure 112. In some embodiments, an interface layer (not shown) is vertically interposed between the capping layer 117 and the second epitaxy region 122. For example, the second epitaxy region 122 is a germanium region, the capping layer is a silicon cap, and the interface layer is a SiGe interface layer.

Referring to FIG. 9 and with reference to FIG. 8, a protective layer 118 may be formed on the capping layer 117 for protection. In some embodiments, the protective layer 118 conformally covers the upper surface 117t of the capping layer 117. For example, the protective layer 118 has an arced upper surface 118t that corresponds to the arced upper surface 117t of the capping layer 117. In some embodiments, the protective layer 118 extends to at least partially cover the upper surface 112a of the isolation structure 112. For example, the protective layer 118 has outer edges that extend outwards past the inner sidewall 112s of the isolation structure 112 and that extend laterally over the upper surface 112a of the isolation structure 112. The protective layer 118 may be or include a low-k dielectric material, or silicon dioxide, silicon nitride, silicon oxynitride, another suitable dielectric material, etc. In some embodiments, the protective layer 118 has a material different than the material of the capping layer 117. For example, the protective layer 118 is an oxide layer, and the capping layer 117 is a silicon cap. The protective layer 118 may (or may not) be thicker than the underlying capping layer 117. In some embodiments, the protective layer 118 and the underlying capping layer 117 are collectively viewed as a capping structure which is configured to protect the underlying epitaxy regions (122 and 121) during the fabrication of the semiconductor structure.

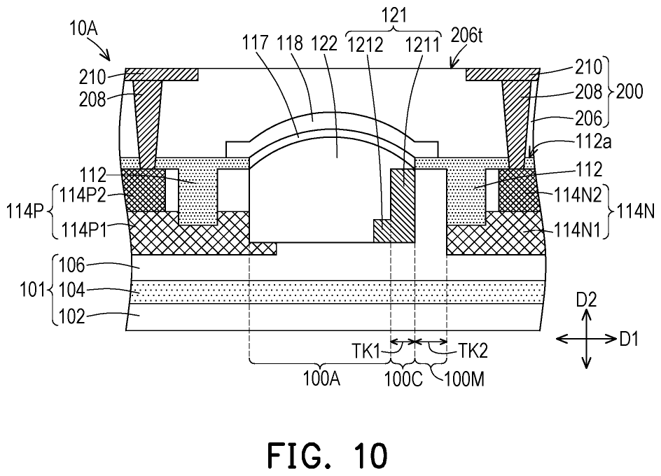

Referring to FIG. 10 and with reference to FIG. 9, a dielectric layer 206 may be formed over the isolation structure 112 and the protective layer 118. The dielectric layer 206 may include one or more stacked inter-layer dielectric (ILD) and inter-metal dielectric (IMD) layers, which may respectively include a low-k dielectric, an oxide, a nitride, a combination thereof, and/or the like. In some embodiments, an uppermost surface 206t of the dielectric layer 206 is substantially planar. In some embodiments, a plurality of conductive contacts 208 (e.g., metal contacts) are formed in the dielectric layer 206 to be electrically coupled to the first doped region 114N and the second doped region 114P. In some embodiments, a plurality of conductive lines 210 (e.g., metal lines) are formed in the dielectric layer 206 and on the conductive contacts 208. The conductive contacts 208 and/or the conductive lines 210 may be or include tungsten, copper, aluminum, gold, nickel, silver, alloy, other suitable conductive material, or a combination thereof. In some embodiments, the dielectric layer 206, the conductive contacts 208, and the conductive lines 210 are part of an interconnect structure 200. Although not shown, it will be appreciated that any number of other conductive features (e.g., conductive lines, conductive pads, and/or conductive vias) of the interconnect structure 200 may be formed over and electrically coupled to the conductive contacts 208 and the conductive lines 210.

In some embodiments, the respective conductive contact 208 extends vertically between the overlying conductive line 210 and the underlying first/second doped region 114N/114P. For example, a first conductive contact of the conductive contacts 208 extends vertically from the first upper region 114N2 of the first doped region 114N to a first conductive line of the conductive lines 210, and a second conductive contact of the conductive contacts 208 extends vertically from the second upper region 114P2 of the second doped region 114P to a second conductive line of the conductive lines 210. The first/second upper region (e.g., 114N2/114P2) may provide a low resistance path between the conductive contacts 208 and the first/second doped region 114N/114P. In some embodiments, the conductive lines 210 are bond pads, the dielectric layer 206 is a bonding dielectric layer, and the bond pads and the bonding dielectric layer are respectively bonded to bond pads and a bonding dielectric layer of a separate semiconductor die/wafer (not shown). In other embodiments, the conductive lines 210 and the conductive contacts 208 are electrically coupled to bond pads that overlie the conductive lines 210 and are disposed in the dielectric layer 206.

With continued reference to FIG. 10, a semiconductor structure 10A merely serves as an illustrative example, and other embodiments may utilize fewer or additional elements. The semiconductor structure 10A may be or include a photonic integrated circuit. In some embodiments, the semiconductor structure 10A includes a photodetector (e.g., an avalanche photodiode (APD) structure). The APD structure may have a separate absorption, charge, and multiplication (SACM) design. For example, the second epitaxy region 122 is configured to be an absorption region 100A of the APD, where the incident light may be absorbed in the absorption region 100A. The first epitaxy region 121 may be configured to be a charge region 100C of the APD, and the second semiconductor layer 106 (e.g., intrinsic silicon) laterally adjacent to the charge region 100C may be configured to be a multiplication region 100M of the APD. In some embodiments, the absorption region 100A is formed of germanium due to its relatively high absorption coefficient (e.g., compared to the absorption coefficient of silicon). In some embodiments, the multiplication region 100M is a portion of the second semiconductor layer 106 laterally between the first epitaxy region 121 and the STI portion of the isolation structure 112. In some embodiments, the charge region 100C is the p-type semiconductor layer (e.g., a SiB layer), and the charge region 100C may be viewed as a p-charge region. The charge region 100C may separate the absorption region 100A from the multiplication region 100M.

The first epitaxy region 121 severing as the charge region 100C may be a semiconductor material (e.g., silicon) with p-type impurities (e.g., boron). It is appreciated that the excess noise factor is related to the impact ionization coefficient ratio. Using the semiconductor material with relatively low impact ionization coefficient (e.g., silicon) may realize a high-performance APD. In some embodiments, the p-type impurities in the first epitaxy region 121 is formed without performing an ion-implant process, since the ion implant bombard may cause a damaged surface of the charge region 100C. The outer surface of the first epitaxy region 121 which does not damage by ion-bombardment may facilitate the growth of the second epitaxy region 122. The ion-implant process under high temperature condition may cause undesirable diffusion into the adjacent layer(s). By forming the first epitaxy region 121 without performing an ion-implant process, the likelihood of the impurity to be undesirably diffused into the second semiconductor layer 106 and the second epitaxy region 122 may eliminated.

By forming the first epitaxy region 121 through the first patterned masking layer 51′ and an epitaxially growing process, a thickness TK1 of the charge region 100C may be precisely controlled. For example, the thickness TK1 measured in the first direction D1 is in a range of about 10 nm and about 200 nm. The electric field of the photodetector may be adjusted by optimizing the dimension (e.g., the thickness) of the charge region 100C. The excess noise may be lowered by configuring the multiplication region 100M with a predetermined thickness TK2. For example, the thickness TK2 measured in the first direction D1 is in a range of about 100 nm and about 300 nm. In some embodiments, a ratio of the thickness TK1 to the thickness TK2 is in a range of about 1/30 and about 2. It should be noted that the thickness values are not intended to limit the embodiments, and the thicknesses of the charge and multiplication regions may vary depending upon the particular application.

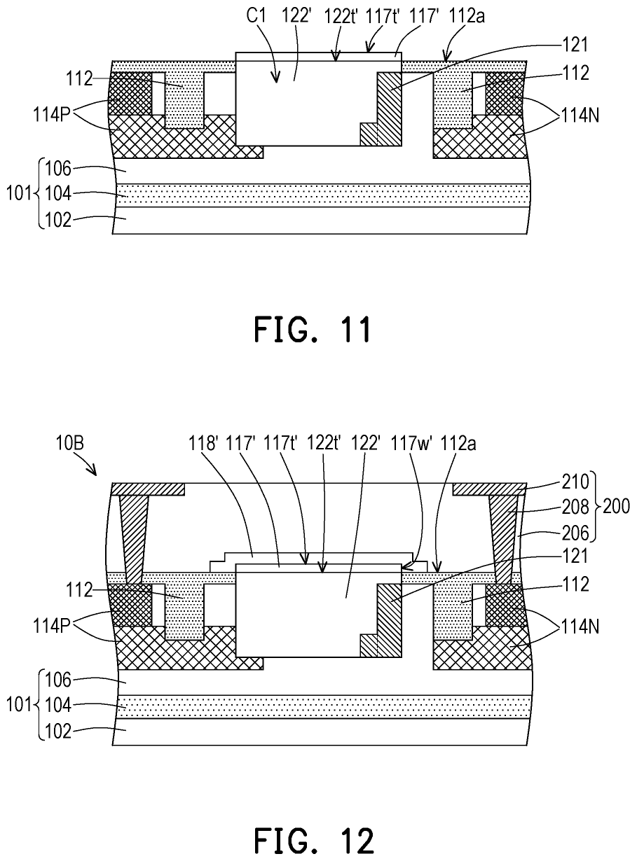

FIGS. 11-12 illustrate schematic cross-sectional views of intermediate stages in the manufacturing of a semiconductor structure with a photodetector, in accordance with some embodiments. Unless specified otherwise, like reference numerals in the present embodiment represent like components in the embodiment shown in FIGS. 1-10. Although method embodiments are discussed as being performed in a particular order, other embodiments may be performed in any logical order.

Referring to FIG. 11 with reference to FIG. 8, the structure illustrated in FIG. 11 may be similar to the structure shown in FIG. 8, except that the upper surface 122t′ of the second epitaxy region 122′ is planarized and the upper surface 117t′ of the capping layer 117′ is substantially flat. For example, after epitaxially growing an epitaxially grown material (e.g., germanium) on the exposed surfaces of the second semiconductor layer 106 and the first epitaxy region 121, a planarization process may be performed on the epitaxially grown material to form the second epitaxy region 122′ with the planarized upper surface 122t′. In some embodiments, the upper surface 122t′ of the second epitaxy region 122′ is substantially leveled (or coplanar) with the upper surface 112a of the passivation portion of the isolation structure 112, within process variations. The capping layer 117′ may then be formed on the upper surface 122t′ of the second epitaxy region 122′. For example, the capping layer 117′ has the flat upper surface 117t′ that corresponds to the planarized upper surface 122t′ of the second epitaxy region 122′.

Referring to FIG. 12 with reference to FIG. 11 and FIGS. 9-10, a protective layer 118′ may be formed on the capping layer 117′. In some embodiments, the protective layer 118′ extends across the upper surface 117t′ of the capping layer 117′. The protective layer 118′ may (or may not) further extend to cover the sidewall 117w′ of the capping layer 117′ and cover at least a portion of the upper surface 112a of the passivation portion of the isolation structure 112 which surrounds the sidewall 117w′ of the capping layer 117′. The protective layer 118′ may have a different configuration than shown. In some embodiments, the dielectric layer 206 is formed over the isolation structure 112 and the protective layer 118′. In some embodiments, the conductive contacts 208 and the conductive lines 210 are formed in the dielectric layer 206 to be electrically coupled to the first doped region 114N and the second doped region 114P. The dielectric layer 206, the conductive contacts 208, and the conductive lines 210 may be a part of the interconnect structure 200. As illustrated by the cross-sectional view of FIG. 12, a semiconductor structure 10B including the second epitaxy region 122′ with the planarized upper surface 122t′ is provided.

Embodiments may have one or a combination of the following features and/or advantages. The semiconductor structure 10A/10B may include high absorption in the second epitaxy region 122 and the low impact ionization coefficient ratio in the first epitaxy region 121 to achieve high bandwidth and low noise. The thickness of the first epitaxy region 121 may be well-controlled by forming the first patterned masking layer 51′ with the opening 51P and epitaxially growing the p-type semiconductor layer in the opening 51P and on the second semiconductor layer 106. The p-type impurity in the first epitaxy region 121 is not formed by an ion implantation process to avoid forming bombardment defects on the first epitaxy region 121, and undesirable diffusion into the second epitaxy region 122 and the adjacent portion of the second semiconductor layer 106 may also be prevented. The improved quality of the first epitaxy region 121 may be achieved, which facilitates the epitaxially growing process of the second epitaxy region 122.

According to some embodiments, a semiconductor structure includes a substrate including a first semiconductor material, a first doped region disposed in the substrate and having a first conductivity type, a second doped region disposed in the substrate and separated from the first doped region, a first epitaxial region disposed in a cavity of the substrate, and a second epitaxial region disposed in the cavity of the substrate and connected to the first epitaxial region. The second doped region has a second conductivity type different than the first conductivity type. The first epitaxial region includes the first semiconductor material with an impurity of the second conductivity type, and the second epitaxial region includes a second semiconductor material different than the first semiconductor material.

According to some embodiments, a semiconductor structure includes a substrate including a first inner sidewall and a second inner sidewall opposite to the first inner sidewall, a first doped region disposed in the substrate and close to the first inner sidewall, a second doped region disposed in the substrate and close to the second inner sidewall, a first epitaxial region connected to the first inner sidewall of the substrate, and a second epitaxial region connected to the second inner sidewall of the substrate and the first epitaxial region. The second doped region has a different conductivity type than the first doped region. The first epitaxial region includes a first semiconductor material with an impurity, and the second epitaxial region includes a second semiconductor material with a different band gap than the first semiconductor material.

According to some embodiments, a manufacturing method of a semiconductor structure includes: forming a first doped region and a second doped region in a substrate, wherein the substrate comprises a first semiconductor material, and the second doped region has a second conductivity type different than a first conductivity type of the first doped region; forming a cavity in a substrate; epitaxially growing a first epitaxial region in the cavity, where the first epitaxial region includes the first semiconductor material with an impurity of the second conductivity type; and epitaxially growing a second epitaxial region in the cavity and on the first epitaxial region, where the second epitaxial region includes a second semiconductor material different than the first semiconductor material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate comprising a first semiconductor material;
a first doped region disposed in the substrate and having a first conductivity type;
a second doped region disposed in the substrate and separated from the first doped region, the second doped region having a second conductivity type different than the first conductivity type;
a first epitaxial region disposed in a cavity of the substrate, the first epitaxial region comprising the first semiconductor material with an impurity of the second conductivity type; and
a second epitaxial region disposed in the cavity of the substrate and connected to the first epitaxial region, the second epitaxial region comprising a second semiconductor material different than the first semiconductor material.

2. The semiconductor structure of claim 1, wherein the substrate comprises a first inner sidewall and a second inner sidewall opposite to the first inner sidewall, the first epitaxial region is connected to the first inner sidewall, and the second epitaxial region is connected to the second inner sidewall.

3. The semiconductor structure of claim 1, wherein the second epitaxial region comprises a curved upper surface protruded from the cavity of the substrate.

4. The semiconductor structure of claim 1, wherein an upper surface of the second epitaxial region extends past an upper surface of the first epitaxial region.

5. The semiconductor structure of claim 1, wherein the first epitaxial region is connected to a first side of the cavity facing the first doped region, and the second epitaxial region is connected to a second side of the cavity facing the second doped region.

6. The semiconductor structure of claim 1, wherein the substrate comprises an inner sidewall and a lower surface connected to the inner sidewall, the first epitaxial region comprises a first portion lining the inner sidewall and a second portion connected to the first portion, and a height of the first portion from the lower surface of the substrate is greater than a height of the second portion from the lower surface of the substrate.

7. The semiconductor structure of claim 1, further comprising:
a capping layer overlying an upper surface of the second epitaxial region.

8. The semiconductor structure of claim 7, wherein the capping layer comprises the first semiconductor material.

9. The semiconductor structure of claim 1, wherein the first and second doped regions, the first and second epitaxial regions, and a portion of the substrate laterally between the first epitaxial region and the first doped region are included in an avalanche photodetector.

10. The semiconductor structure of claim 9, wherein the second epitaxial region acts as an absorption region of the avalanche photodetector, the first epitaxial region acts as a charge region of the avalanche photodetector, and the portion of the substrate acts as a multiplication region of the avalanche photodetector.

11. A semiconductor structure, comprising:
a substrate comprising a first inner sidewall and a second inner sidewall opposite to the first inner sidewall;
a first doped region disposed in the substrate and close to the first inner sidewall;
a second doped region disposed in the substrate and close to the second inner sidewall, the second doped region having a different conductivity type than the first doped region;
a first epitaxial region connected to the first inner sidewall of the substrate, the first epitaxial region comprising a first semiconductor material with an impurity; and
a second epitaxial region connected to the second inner sidewall of the substrate and the first epitaxial region, the second epitaxial region comprising a second semiconductor material with a different band gap than the first semiconductor material.

12. The semiconductor structure of claim 11, wherein the first doped region comprises n-type dopants, the second doped region comprises p-type dopants, and the first epitaxial region comprises a p-type impurity.

13. The semiconductor structure of claim 11, wherein an upper surface of the second epitaxial region arcs between and is connected to the first and second inner sidewalls of the substrate.

14. The semiconductor structure of claim 11, wherein the second epitaxial region overlies an uppermost surface of the first epitaxial region.

15. The semiconductor structure of claim 11, wherein the first epitaxial region comprises a first portion connected to the first inner sidewall of the substrate and a second portion connected to the first portion, and a dimension of the first portion is greater than that of the second portion.

16. The semiconductor structure of claim 11, wherein the first and second doped regions, the first and second epitaxial regions, and a portion of the substrate laterally between the first epitaxial region and the first doped region are included in an avalanche photodetector.

17. A manufacturing method of a semiconductor structure, comprising:
forming a first doped region and a second doped region in a substrate, wherein the substrate comprises a first semiconductor material, and the second doped region has a second conductivity type different than a first conductivity type of the first doped region;
forming a cavity in a substrate;
epitaxially growing a first epitaxial region in the cavity, wherein the first epitaxial region comprises the first semiconductor material with an impurity of the second conductivity type; and
epitaxially growing a second epitaxial region in the cavity and on the first epitaxial region, wherein the second epitaxial region comprises a second semiconductor material different than the first semiconductor material.

18. The manufacturing method of claim 17, further comprising:
forming a patterned mask layer in the cavity to expose a first inner sidewall of the substrate and a portion of a lower surface of the substrate connected to the first inner sidewall; and
epitaxially growing the first epitaxial region on the first inner sidewall and the portion of the lower surface of the substrate.

19. The manufacturing method of claim 18, further comprising:
removing the patterned mask layer; and
epitaxially growing the second epitaxial region on a second inner sidewall of the substrate, a rest portion of the lower surface of the substrate, and on the first epitaxial region.

20. The manufacturing method of claim 17, further comprising:
forming a capping layer on the second epitaxial region, wherein the capping layer comprises the first semiconductor material.
